(19) United States
(12) Patent Application Publication
(10) Pub. No.: US 2016/0005623 A1
(43) Pub. Date: Jan. 7, 2016

(54) METHOD FOR PURIFYING METALLURGICAL SILICON

(71) Applicant: Prised Solar Inc., Toronto, Ontario (CA)

(72) Inventors: Wahid Shams-Kolahi, Toronto, Ontario (CA); Harry Ruda, Toronto, Ontario (CA); Christina F Souza, Toronto, Ontario (CA)

(21) Appl. No.: 14/653,580

(22) PCT Filed: Dec. 19, 2013
(86) PCT No.: PCT/CA2013/050991

§ 371 Date: Jun. 18, 2015

Related U.S. Application Data
(60) Provisional application No. 61/745,114, filed on Dec. 21, 2012.

(51) Int. Cl. H01L 21/322

(52) U.S. Cl. CPC H01L 21/3221; H01L 21/3228

(57) ABSTRACT

The present disclosure provides a method for upgrading materials, for example crystalline metallurgical silicon, to remove impurities using microwave processing to induce migration of impurities in the material to one or both of internal surfaces where they are trapped and neutralized or one or more external surfaces followed by trapping of the impurity by binding to gettering agents on the surface with subsequent removal of the impurity and gettering agent.

### CROSS REFERENCE TO RELATED U.S PATENT APPLICATIONS

This patent application relates to, and claims the priority benefit of U.S. Provisional Application Ser. No. 61/745,114 filed Dec. 21, 2012, which is incorporated herein in its entirety by reference.

### FIELD OF THE INVENTION

The present disclosure relates to a method for purifying (upgrading) materials, such as crystalline metallurgical grade silicon, and other semiconductors, by removing or neutralizing impurities using a combination of microwave processing and internal and external gettering. More particularly the present method uses microwave processing to induce migration of impurities in materials to either internal interfaces where the impurities are trapped and neutralized (internal gettering), or to external surfaces followed by trapping (external gettering) with the subsequent removal of the impurities.

### BACKGROUND

Current refining of metallurgical grade Si (MG-Si) and other semiconductors involves a sequence of processes where each process is dedicated to lower the concentration of specific impurities to suitable levels for the photovoltaic industry^{[1,2]}. These processes typically require a high consumption of energy and often result in large amounts of hazardous byproducts or chemical waste^{[3-8]}. Solidification refining, for example, is effective in the removal of some impurities, but needs to be applied at least twice in order to lower Fe concentrations to acceptable levels^{[9]}. The development of alternatives is a necessity to protect the environment by reducing the energy consumption and chemical waste, as well as to reduce costs and increase the efficiency of purification.

### SUMMARY

The present disclosure relates to a method for purifying or upgrading materials by removing impurities using microwave processing to induce migration of impurities in the material to regions such as interfaces, grain boundaries, etc., where they can be trapped and neutralized, as well as to surfaces where they can be removed.

An embodiment provides a method for removing impurities from a material, the material being anyone of a semiconductor, comprising irradiating the material with microwave radiation with power in a range from about 0.3 kW to about 300 kW, at a frequency in a range from about 300 MHz to 600 GHz for a selected period of time to cause microwave thermal and field induced migration of impurities to one or more internal interfaces at which the impurities are trapped and neutralized and/or to one or more exterior surfaces having located thereon gettering agents at which the impurities bind with the gettering agent. Gettering sites on the external surface having impurities bound thereto are removed.

An embodiment provides a method for removing impurities from semiconductors, comprising irradiating a semiconductor with microwave radiation with power in a range from about 0.3 kW to about 300 kW, at a frequency in a range from about 300 MHz to 600 GHz for a selected period of time to cause microwave thermal and field induced migration of impurities to one or more internal interfaces at which the impurities are trapped and neutralized and/or to one or more exterior surfaces having located thereon gettering agents at which the impurities bind with the gettering agent, and for impurities bound on the one or more external surfaces, removing the gettering agents.

Another embodiment provides a method for removing impurities from metallurgical silicon, comprising: irradiating metallurgical silicon with microwave radiation with power in a range from about 0.3 kW to about 300 kW, at a frequency in a range from about 300 MHz to 600 GHz for a selected period of time to cause microwave thermal and field induced migration of impurities to one or more internal interfaces at which the impurities are trapped and neutralized and/or to one or more exterior surfaces having located thereon gettering agents at which the impurities bind with the gettering agent; and for impurities bound on the one or more external surfaces, removing the gettering agents.

Another embodiment provides a method for removing impurities from materials, comprising: irradiating a material with microwave radiation for a selected period of time at a power level sufficient to cause thermal and field induced migration of impurities to one or more internal interfaces at which the impurities are trapped and neutralized and/or to one or more exterior surfaces having located thereon gettering agents at which the impurities bind with the gettering agent; and for impurities bound to the gettering agent on the one or more external surfaces, removing the gettering agents.

A further understanding of the functional and advantageous aspects of the disclosure can be realized by reference to the following detailed description and drawings.

### BRIEF DESCRIPTION OF THE DRAWINGS

Embodiments of the method for purifying materials will now be described, by way of example only, with reference to the drawings, in which:

FIG. 1 shows the electrochemical capacitance-voltage (ECV) profiles of silicon wafers ion implanted with Fe: before microwave processing (full circles) and after microwave treatment (hollow circles).

FIG. 2 illustrates ECV profiles of silicon wafers doped with boron: before microwave processing (full triangles) and after microwave treatment; with uninterrupted application of microwaves for 520 s (solid squares) and with application of microwaves 4 times for 130 s totaling 520 s (hollow circles).

FIG. 3 shows the microwave induced change in the carrier concentration as a function of sample temperature. Samples are p-type (boron-doped) silicon wafers upon which was deposited a phosphorus-based glass layer. The changes in carrier concentration (full squares) are obtained from ECV profiles measured after microwave treatment under different powers for the same amount of time (i.e., 600 s). Plotted data is taken from the full position-dependent curves and evaluated at a fixed depth of 0.2 μm. The temperature corresponding to each power was estimated from the measured ECV profiles. The solid line is fit based on the solution of Fick's second law of diffusion for a constant source (i.e., phosphorus) at the surface of the sample. The activation energy for diffusion of 2.05±0.04 eV is obtained. The figure also shows that for temperatures below a threshold (i.e., hatched region), there is insufficient energy for diffusion.

FIG. 4 presents the carrier concentration as a function of depth, which is measured by ECV profiling. The sample is n-type (Si-doped) GaAs plated with zinc. The solid line is a fit from Fick's second law of diffusion for a constant source (i.e., zinc) at the surface of the sample. The experimental data (full squares) is fit assuming a temperature of 990.2±4.2° C. for the diffusion process.

FIG. 5 displays a plot of microwave penetration depth calculated as a function of microwave frequencies for semiconductors of various conductivities. The penetration depth is defined as the depth into the sample at which the effect of microwave field drops by a factor of 1/e or the power absorbed is half as much as it is at the sample surface^{[12]}. The penetration depth increases with the reduction of both semiconductor conductivity and the microwave frequency.

### DETAILED DESCRIPTION

Various embodiments and aspects of the disclosure will be described with reference to details discussed below. The following description and drawings are illustrative of the disclosure and are not to be construed as limiting the disclosure. The drawings are not to scale. Numerous specific details are described to provide a thorough understanding of various embodiments of the present disclosure. However, in certain instances, well-known or conventional details are not described in order to provide a concise discussion of embodiments of the present disclosure.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure.

As used herein, the phrases “gettering” and “gettering agents” and “gettering sites” means a process in which impurities in a certain region of the silicon wafer are reduced by moving and localizing them in predetermined locations (called gettering sites) from where they can be removed or neutralized. Typical gettering agents include, but are not limited to, phosphorous, aluminum-hydrates. sulfur-oxides and any combination thereof.

As used herein, the phrase “electrochemical capacitance-voltage (ECV) profiling” refers to a technique where the Schottky metal contact of a conventional capacitance-voltage (CV) measurement of a semiconductor is replaced by an electrolyte that is used to sequentially etch the semiconductor and determine the capacitance at each etch step. The carrier concentration profile is determined from the measured differential capacitance. The result is the profile of carrier concentration from the semiconductor surface to the etched depth.

As used herein, the phrase “surface photovoltage (SPV) method” refers to the well-established contactless technique for characterization of semiconductors where changes in the semiconductor surface voltage due to illumination are analyzed. An important parameter that can be obtained with this technique is the minority carrier diffusion length. The minority carrier diffusion length is the average length a carrier moves before it recombines. It is an important quality of semiconductors because larger values for diffusion lengths are an indication of longer recombination lifetimes, Longer recombination times are necessary for obtaining a higher efficiency of solar cells.

As used herein, the phrase “metallurgical grade silicon” (MG-Si) means silicon commercially produced through the reduction of silicon oxide (quartz) with carbon in submerged arc furnaces. With purity typically in the range, but not limited to, of 98.5-99.5 wt % Si, it is the starting material in the production of pure silicon for photovoltaic and electronic industries. Typical impurities that are found in MG-Si are Fe, Sb, As, Cu, Al, Cr, Mn, to mention a few.

As used herein, the phrase “susceptor” means a silicon carbide piece. Because silicon carbide is a good absorber of microwaves by converting them into heat, its function is to help heat up a sample that is put in direct contact with it.

The present disclosure discloses a method for upgrading crystalline metallurgical grade silicon to remove impurities using microwave processing to induce migration of impurities in silicon wafers, coupled with established methods (such as gettering technology) to trap and remove the impurities. The method can be applied in between stages of standard processes of purification of silicon (such as acid leaching, unidirectional solidification, metal liquating^{[3-8]}, to mention just a few) to wafers, pellets or particles of MG-Si or upgraded MG-Si.

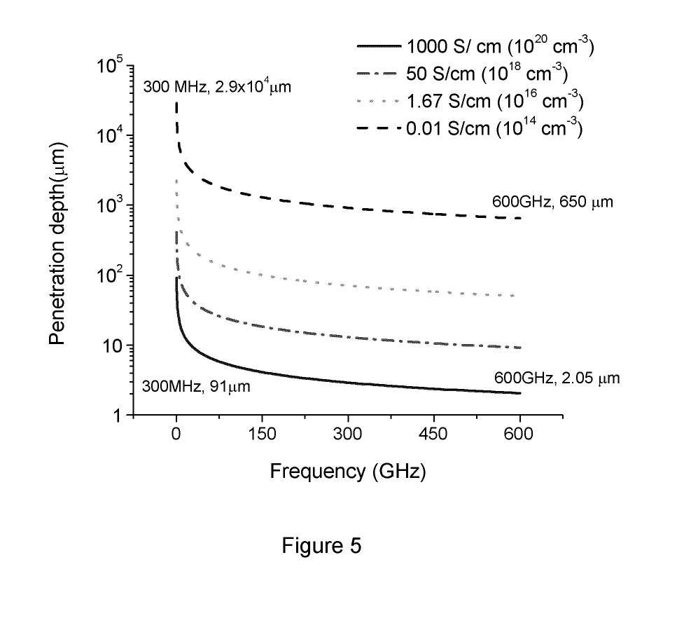

The microwave chamber can be designed according to the needs of the process, i.e. with closed cavity, conveyors, belt, under vacuum or controlled gas atmospheres. The microwave chamber can be designed to select different microwave modes and magnetrons or gyrotrons can be shaped to produce different frequencies. Considering that the penetration depth of the microwaves depends inversely on the frequency, having access to cavities with different frequencies would allow impurities at different depths inside the crystal to be reached and moved with more control as is demonstrated in FIG. 5. The microwave power absorbed on the surface of the semiconductor depends on its conductivity^{[12]}. The absorbed power increases as the semiconductor conductivity is lowered down to certain limits. Systems built with frequencies in the range between 300 MHz and 600 GHz, with power between 0.3 kW and 300 kW, but not limited to, allows for purification of semiconductors with different wafer thicknesses, pellet or particle sizes, and electronic properties.

The microwave cavity or chamber can be designed with scatterers that would allow a higher uniformity of the microwave beam for volumetric heating. Mode scatterers are rotating plates that reflect the microwaves inside the cavity making the electromagnetic field distribution more homogeneous.

Another option is the use of a focusing mirror to concentrate the beam in a smaller region when surface heating is needed or small areas. In addition, cavity walls with air or water cooling systems would help avoid overheating of the chamber.

The exposure time of the semiconductor to the microwave will depend on the type of impurities as well as microwave parameters involved, specifically frequency and power. It also will depend on the amount of material to be purified at once. Typically exposure times can vary from tenths of a second to up to ½ hour for most impurities for frequencies in the range from 300 MHz and 600 GHz and powers in the range from about 0.3 kW to about 300 kW.

In the method disclosed herein, the upgrade of impure low-quality crystalline silicon (such as metallurgical silicon) or other semiconductors (such as but not limited to germanium, GaAs, InGaAs, and InP) is obtained by the combination of microwave processing and gettering. Gettering techniques are already widely used in the photovoltaic (PV) industry as one of the final steps in the purification of silicon. The method disclosed herein makes use of microwaves for inducing the migration of impurities. This occurs through coupling of microwave energy to the carrier system which causes an internal electric field as well as induced local heating. These effects cause migration of impurities to gettering sites from which they can subsequently be neutralized (in the case of trapping along internal interfaces such as grain boundaries, interfaces with other materials such as contacts or absorbers or removed from the external surface by the presence of gettering agents on the surface, which are subsequently removed once the process is complete.

The utilization of microwaves for inducing migration of impurities within the material to gettering sites can improve energy consumption in at least one of the steps of purification of MG-Si and, consequently, lowering the costs. Also, the option of using this as one of the steps of one specific sequence of purification processes in a more efficient way, avoids the use of other methods (as cited above) that have a larger impact in the environment due to generation of byproducts and chemical waste, as well as, energy consumption.

### Purification of Metallurgical Grade Silicon

To study the efficacy of using microwaves for purification of silicon, silicon wafers were doped with iron (Fe) and boron (B).

In the first case, test samples of crystalline silicon wafers were ion implanted with Fe in order to create an impurity profile that could be calculated via Monte Carlo modeling and characterized using electrochemical capacitance-voltage (ECV) profiling. The samples are divided to keep pieces to be used as control samples and pieces to be submitted to microwave processing. The microwave processing comprises exposing samples to microwave radiation for controlled times in a microwave cavity. The samples were characterized before and after microwave processing by ECV.

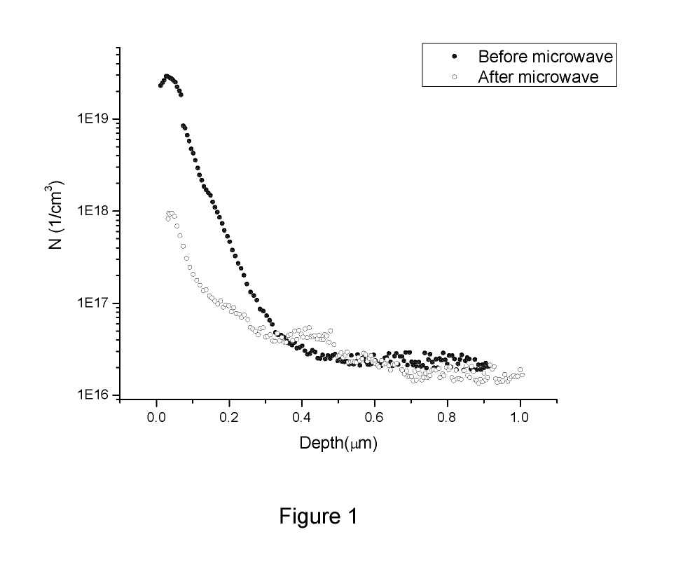

Characteristic results are shown in FIG. 1. In this specific case, the sample was microwave processed for 45 s, with a power of 3 kW, and at a frequency of 2.45 GHz. There is a large change in the measured profile after microwave treatment (hollow circles curve) when compared to the control sample (full circles curve). Even in such a short time, the microwave radiation caused a migration of the impurities present in the sample.

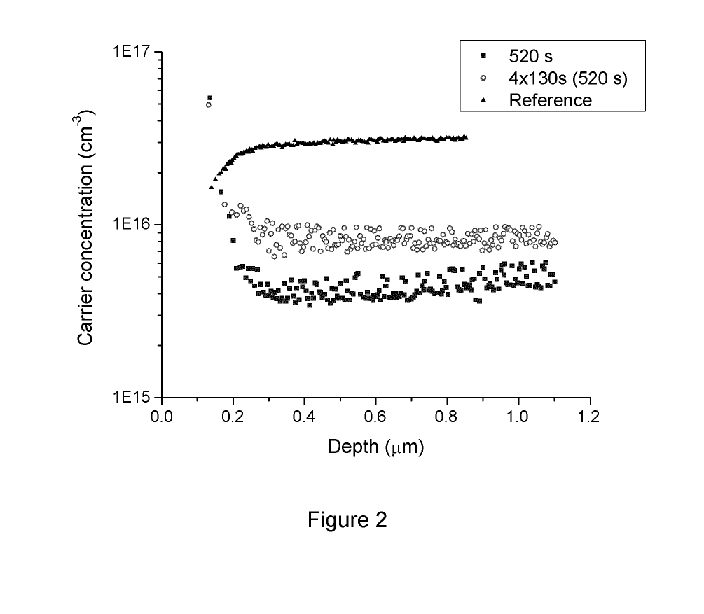

In another study the cumulative effect of microwave treatment was studied. In this study a piece of B doped Si (resistivity of 0.3-0.6 Ωcm) was positioned inside a microwave cavity and the power was switched on for 520 s (8 min. 40 s.) at a power of 1.5 kW without pause. Another sample was then submitted to the same microwave power for 4 times 130 s, accumulating the same total time period used for the first sample. Between intervals, the cavity was opened for 5 min to allow for the cooling down of the sample. This experiment allows an inference of the contribution of thermal effects to the migration of impurities. With continuous processing, thermal diffusion can readily occur as opposed to interrupted processing. The measured curves seen in FIG. 2 show that uninterrupted treatment is more effective than that with interruption in the redistribution of impurities.

In an embodiment of the method for purifying MG-silicon, a susceptor such as a silicon carbide plate is disposed beneath a silicon sample for processing. In this case, the high microwave absorption of silicon carbide results in a significant fraction of microwave power being absorbed by the susceptor which consequently heats up. With samples to be processed disposed on the susceptor, heat is transferred to the silicon samples by both conduction and radiation. This embodiment thus enables a thermal bias to be effected during processing, to further enhance the migration of impurities during microwave processing.

In another study the influence of microwave radiation and phosphorus gettering on a MG-silicon wafer was studied. As test samples, a MG-silicon wafer with a purity of 98 wt % Si was prepared with a layer of phosphorus, as a gettering agent, deposited on the outer surface using the spin-on-glass method. A piece of the same wafer was used, without the phosphorus deposition as a reference sample. The piece of wafer with the phosphorus layer receives microwave treatment for 600 s (10 min) at a power of 1.5 kW. After the treatment, the phosphorus glass layer was removed from the sample and the minority carrier diffusion length was measured by the aforementioned surface photovoltage technique. The obtained value was then compared with the minority carrier diffusion length measured for the reference sample. This study demonstrated that microwaves applied in conjunction with phosphorus gettering to MG-Si increase the minority carrier diffusion length from 32 μm to 110 μm. Considering that the sample is p-type with a doping level of 2.6×10¹⁸ cm⁻³ (measured by ECV profiling) this enhancement of minority carrier diffusion length corresponds to an improvement of recombination lifetime from an initial value (before microwave treatment) of 2.2×10⁻⁶ s to a processed value of 2.7×10⁻⁵ s. That is, the microwave processing of the MG-silicon wafer very surprisingly increased the recombination lifetime by about 10 times.

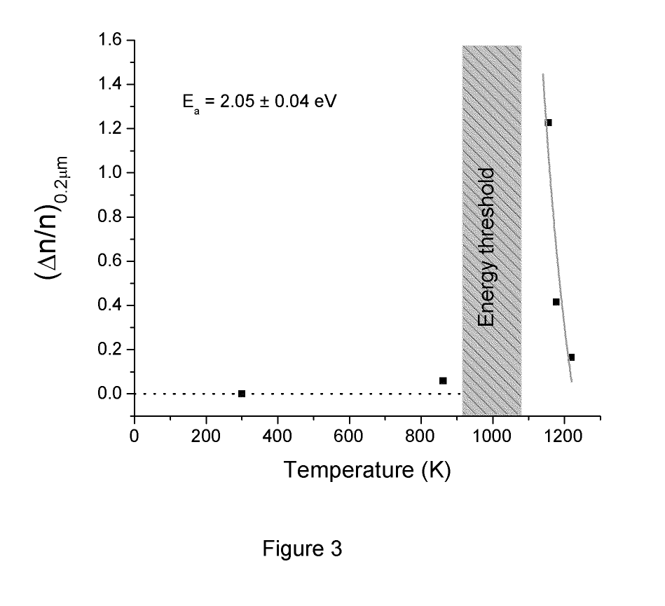

In another study, the influence of microwave power on phosphorus gettering was studied. Test samples of MG-silicon wafers with a purity 98 wt % Si were prepared with a layer of phosphorus deposited on the surface using the spin-on-glass method. A sample of the same material, without the phosphorus deposited on its surface, was used as a reference. The phosphorus-coated silicon wafer was microwave treated for 600 s (10 min) at powers of 1.0, 1.5, 2.4, and 3.0 kW. After treatment, the phosphorus glass layer was removed from the sample and the carrier concentration was measured as a function of depth using ECV profiling. The difference between profiles for microwave treated coated samples and the reference sample was calculated, reflecting the in-diffusion of phosphorus. FIG. 3 shows results for a depth of 0.2 μm from the surface and shows three distinct regions. At low temperatures, there is no change in carrier concentration, corresponding to phosphorus diffusion being inactive (dotted line region). Once a threshold temperature is overcome (see hatched region), phosphorus diffuses into silicon wafer (far right region on FIG. 3). The temperatures corresponding to each power were estimated from the measured ECV profiles. The curve in the phosphorus diffusion region (solid line) was fit using Fick's second law of diffusion for a constant source (of phosphorous) at the surface of the sample. A value for activation energy for phosphorus diffusion of 2.05±0.04 eV was obtained from the fit, agreeing well with the published value for the activation energy for phosphorous diffusion in silicon (i.e., 2.1 eV)^{[10]}. This study demonstrates that microwave processing of MG-Si with power exceeding a threshold, and when applied for sufficient time, even as small as 600 s, can cause phosphorus in-diffusion.

### Purification of GaAs

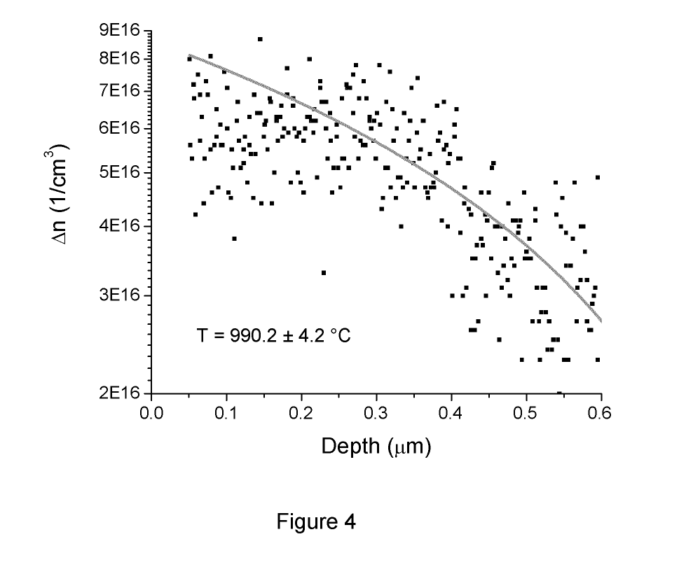

An n-type GaAs wafer was divided in half with one part used as a reference sample and the other part was prepared with a layer of zinc deposited on the surface using thermal evaporation. The wafer with a zinc layer received microwave treatment for 240 s (4 min) at a power of 3.0 kW. After treatment, the surface zinc layer was removed from the sample, and the carrier concentration was measured as a function of depth using ECV profiling. The diffusion profile obtained from the measured curve (shown as solid squares in FIG. 4) was then fit using Fick's second law of diffusion for a constant source of zinc at the surface (solid line). Using the published value for the diffusivity of zinc in GaAs rapid thermal annealing^{[11]}, a diffusion temperature of 990±4.2° C. is obtained. This study showed that microwave processing, even if applied for only 240 s, causes diffusion of zinc in the GaAs wafer.

A system for purifying metallurgical grade silicon may include steps that involve various processes to remove impurities, such as directional solidification, slag refining, acid leaching, vacuum refining, plasma refining, solvent refining, to site some of them. Different manufacturers use different sequences or combinations of processes to get to the required level of purity for the photovoltaic industry. In most of these sequences of processes, a critical point is the removal of boron and phosphorous. The method disclosed herein may be used in conjunction with other methods or it may replace one or more steps with reduction of energy consumption and residual chemical waste. It may be used, for example as a step for removal of impurities that are usually removed with directional solidification decreasing or eliminating the need of executing it to bring the concentration of impurities to the required levels for the photovoltaic industry.

### Purify Other Materials

While the present method has been discussed with respect to purifying metallurgical grade silicon for the photovoltaic industry it will be appreciated that, as shown above, it may be used for purifying other semicondcutors and thus has wide utility in purifying materials for microelectronics in general.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

### REFERENCES

[1] J. Kraiem, B. Drevet, F. Cocco, N. Enjalbert, S. Dubois, D. Camel, D. Grosset-Bourbange, D. Pelletier, T. Margaria, and R. Einhaus 35th IEEE Photovoltaic Specialists Conference (PVSC), June 2010, Honolulu, Hi., USA, p. 001427.
[2] Wu H., Ma W., Chen X., Jiang Y., Mei X., Zhang C., and Wu X. Trans. Nonferrous Met. Soc. China 21, 1340 (2011).
[3] Ma X., Zhang J. Wang T., and Li T. Rare Metals 28, 221 (2009).
[4] D. Lu, Y. Hu, T. Lin, Y. Liu, B. Wang, Y. Sun, H. Chen, and Q. Li Advanced Materials Research 156-157, 566 (2011).
[5] Zhao L.-X., Wang Z., Guo Z.-C., and Li C.-Y. Trans. Nonferrous Met. Soc. China 21, 1185 (2011).
[6] A. F. B. Braga; S. P. Moreira; P. R. Zampieri; J. M. G. Bacchin; P. R. Mei Steinfeld Solar Energy Materials and Solar Cells 92, 418 (2008).
[7] A. M. Mitra\check{s}inovié and T. A. Utigard Silicon 1, 239 (2009).
[8] M. A. Martorano, J. B. Ferreira Neto, T. S. Oliveira, and T. O. Tsubaki Materials Science & Engineering B 176, 217 (2011).
[9] K. Morita, T. Miki Intermetallics 11, 1111 (2003).
[10] A. Bentzen, A. Holt, J. S. Christensen, and B. G. Svensson J. Appl. Physics 99, 064502 (2006).
[11] N. Nordell, P. Ojala, W. H. Van Berlo, G. Landgren, and M. K. Linnarsson J. Appl. Physics 67, 78 (1990).
[12] H. Zohm, E. Kasper, P. Mehringer, and G. A. Muller Microelectronic Engineering 54, 247 (2000).

1. A method for removing impurities from semiconductors,
comprising: irradiating a semiconductor with microwave radiation with power in a range from about 0.3 kW to about 300 kW, at a frequency in a range from about 300 MHz to 600 GHz for a selected period of time to cause microwave thermal and field induced migration of impurities to one or more internal interfaces at which the impurities are trapped and neutralized and/or to one or more external surfaces having located thereon gettering agents at which the impurities bind with the gettering agent; and
for impurities bound to the gettering agent on the one or more external surfaces, removing the gettering agents.

2. The method according to claim 1 wherein the gettering agents are removed by any one or combination of chemical etching, and acid leaching.

3. The method according to claim 1 including varying the frequency of irradiation in said power and frequency range.

4. The method according to claim 1 including placing the semiconductor on a susceptor material more susceptible to microwave heating for locally raising the temperature of the semiconductor during microwave processing.

5. The method according to claim 4, wherein said susceptor material is a microwave absorbing ceramic.

6. The method according to claim 5, wherein said susceptor material any one of silicon carbide and alumina.

7. The method according to claim 1 wherein said selected period of time is from seconds to ½ hour.

8. The method according to claim 1 wherein said semiconductor is metallurgical grade silicon.

9. The method according to claim 1 wherein said semiconductor is any one of germanium, GaAs, InGaAs, and InP.

10. The method according to claim 1 wherein said semiconductor is in the shape of a wafer or pellets.

11. The method according to claim 1 wherein said semiconductor is any one of crystalline, or polycrystalline material.

12. (canceled)

13. The method according to claim 1 wherein said gettering agents include any one of phosphorous, aluminum-hydrates. sulfur-oxides and any combination thereof.

14. A method for removing impurities from metallurgical silicon, comprising:
irradiating metallurgical silicon with microwave radiation with power in a range from about 0.3 kW to about 300 kW, at a frequency in a range from about 300 MHz to 600 GHz for a selected period of time to cause microwave thermal and field induced migration of impurities to one or more internal interfaces at which the impurities are trapped and neutralized and/or to one or more external surfaces having located thereon gettering agents at which the impurities bind with the gettering agent; and
for impurities bound on the one or more external surfaces, removing the gettering agents.

15. A method for removing impurities from materials, comprising:
irradiating a material with microwave radiation for a selected period of time at a power level sufficient to cause thermal and field induced migration of impurities to one or more internal interfaces at which the impurities are trapped and neutralized and/or to one or more external surfaces having located thereon gettering agents at which the impurities bind with the gettering agent; and
for impurities bound to the gettering agent on the one or more external surfaces, removing the gettering agents.

16. The method according to claim 15 wherein the power level sufficient to cause thermal and field induced migration of impurities is in a range from about 10 Watts to about 300 kWatts, and the frequency is in a range from about 300 MHz to 600 GHz.

17. The method according to claim 15 wherein the gettering agents are removed by any one or combination of chemical etching, and acid leaching.

18. The method according to claim 15 including varying the frequency of irradiation in said power and frequency range.

19. The method according to claim 15 including placing the material on a susceptor material more susceptible to microwave heating for locally raising the temperature of the semiconductor during microwave processing.

20. The method according to claim 19, wherein said susceptor material is a microwave absorbing ceramic.

21. The method according to claim 20, wherein said susceptor material any one of silicon carbide and alumina.

22. The method according to claim 15 wherein said selected period of time is from seconds to ½ hour.

23. The method according to claim 15 wherein said material is metallurgical grade silicon.

24. The method according to claim 15 wherein said material is a semiconductor.

25. The method according to any one of claim 24 wherein said semiconductor is any one of germanium, GaAs, InGaAs, and InP.

26. The method according to claim 15 wherein said material is in the shape of a wafer or pellets.

27. The method according to claim 24 wherein said semiconductor is any one of a crystalline and polycrystalline semiconductor.
